(19) United States
(12) Patent Application Publication
(10) Pub. No.: US 2021/0199430 A1
(43) Pub. Date: Jul. 1, 2021

(54) METHOD AND DEVICE FOR MEASURING FLATNESS OF A FLEXIBLE PHOTOVOLTAIC MODULE

(71) Applicant: MiaSole Equipment Integration (Fujian) Co., Ltd., Quanzhou, Fujian (CN)

(72) Inventors: Lin Liu, Quanzhou, Fujian (CN); Tao Li, Quanzhou, Fujian (CN); Qiang Yuan, Quanzhou, Fujian (CN); Jing Zeng, Quanzhou, Fujian (CN); Shiyang Sun, Quanzhou, Fujian (CN); Chongyan Lian, Quanzhou, Fujian (CN); Zhaoxiong Huang, Quanzhou, Fujian (CN)

(21) Appl. No.: 16/076,947

(22) PCT Filed: Jul. 13, 2018
(86) PCT No.: PCT/CN2018/095629

§ 371 Date: Aug. 9, 2018

(30) Foreign Application Priority Data
Oct. 24, 2017 (CN) 201721381579.6

(51) Int. Cl. G01B 21/30; H02S 50/00; H01L 31/0392

(52) U.S. Cl. CPC G01B 21/30; H01L 31/03926; H02S 50/00

(57) ABSTRACT

The present disclosure discloses a method and a device for measuring flatness of a flexible photovoltaic module, comprising: a measurement platform configured to fix a to-be-measured flexible photovoltaic module, height measurers respectively corresponding to wave crests and wave troughs on the to-be-measured flexible photovoltaic module, the plurality of height measurers being located above the measurement platform, and a lift rack on which the plurality of height measurers are disposed. According to the present disclosure, by lowering of the lift rack, the height measurers are driven to come into contact with the respective wave crests and wave troughs on the to-be-measured flexible photovoltaic module, so as to measure the height of the wave crests and the wave troughs, which reduces measurement errors brought forth by the fact that the measurement cannot be performed in proper time due to local deformation of the cell module, moreover, due to the support of the lift rack, there is no need to manually move the measuring device back and forth, which thereby reduces the measuring device's scratching the to-be-measured flexible photovoltaic module, and in addition, the present disclosure enables direct and simultaneous measurement of a plurality of wave crests and wave troughs, which greatly improves the measuring efficiency.

### CROSS-REFERENCE TO RELATED APPLICATIONS

This application is a 371 U.S. National Phase of International application No. PCT/CN2018/095629, filed Jul. 13, 2018, and claims benefit/priority of Chinese patent application No. 201721381579.6, filed with the Chinese Patent Office on Oct. 24, 2017, and entitled “Device for Measuring Flatness of a Flexible Photovoltaic Module”, the contents of all of which are incorporated herein by reference in entirety.

### TECHNICAL FIELD

The present disclosure relates to the field of processing of photovoltaic cell, particularly to a method and a device for measuring flatness of a flexible photovoltaic module.

### BACKGROUND ART

Compared with the traditional rigid solar cell modules, the flexible solar cell modules are lightweight, thin and bendable, and have a wider range of application. However, due to the difference in the thermal expansion coefficient among the various laid materials of the flexible module, especially to the great difference in the expansion coefficient between the bus-bars made of tinned copper tapes, and the polymer materials of the front panel, the back panel, and the encapsulation adhesive film, the laminated cell module takes a wavy appearance, in which the wave crests and the wave troughs appear regularly in an alternate manner, which severely affects the appearance quality of the module, and the modules on which the height difference between wave crests and wave troughs has exceeded the specification have to be picked out.

At present, the prevailing detection method is by manually using a movable statoscope. However, measurement by using this instrument has the following defects: 1. since the instrument itself has a certain weight, the cell module will experience local deformation at the time of performing manual measurement, which will result in measurement errors as measurement is not performed in time, 2. during measurement, the probe needs to be manually moved frequently in order to obtain the height data of the highest point and the lowest point, and moving the probe back and forth will easily scratch the cell module and thereby affect the service life of the cell module, and 3. manual measurement has a low speed, and requires manual recording the measurement data and making a judgment as to whether the cell module is qualified, which greatly affects the working efficiency.

### SUMMARY

It is an object of the present disclosure to provide a method and a device for measuring flatness of a flexible photovoltaic module, so as to solve the problems in the prior art, reduce measurement errors due to local deformation of the cell module, reduce scratches on the cell module and improve the working efficiency.

The present disclosure provides a device for measuring flatness of a flexible photovoltaic module, comprising:
a measurement platform configured to fix a to-be-measured flexible photovoltaic module,
height measurers respectively corresponding to wave crests and wave troughs on the to-be-measured flexible photovoltaic module, the plurality of height measurers are located above the measurement platform, and
a lift rack on which the plurality of height measurers are disposed.

Preferably, the lift rack is arranged to perform lifting and lowering on the measurement platform, on the ground, or in suspension.

Preferably, the lift rack comprises a support frame and a lifting drive unit, wherein the plurality of height measurers are sequentially disposed on the support frame, and the support frame is fixed on the measurement platform via the lifting drive unit.

Preferably, the lifting drive unit comprises two cylinders, wherein telescopic rods of the two cylinders are connected with two ends of the support frame, respectively, and cylinder bodies of the two cylinders are both fixed on the measurement platform.

Preferably, the lifting drive unit comprises a lifting rope, and the lifting rope is connected with the support frame.

Preferably, the height measurer is a height measuring probe, and the plurality of height measuring probes are arranged in a straight line.

Preferably, the device for measuring flatness of a flexible photovoltaic module further comprises a data collector, and the data collector is connected with each of the height measurers.

Preferably, the device of measuring flatness of a flexible photovoltaic module further comprises a controller, and the controller is connected with both the lifting drive unit and the data collector.

Preferably, the device for measuring flatness of a flexible photovoltaic module further comprises a display, and the display is connected with the controller.

Preferably, the support frame is provided thereon with a slide rail, and each of the height measurers are slidably mounted on the slide rail.

Preferably, there is further provided a positioning clamping element, wherein the positioning clamping element is disposed on the slide rail and configured to position each of the height measurers.

Preferably, there is further provided a positioning apparatus, wherein the positioning apparatus is disposed on the measurement platform and configured to fix the to-be-measured flexible photovoltaic module, and the positioning apparatus is plural in number.

Preferably, there is further provided a sliding apparatus, wherein the sliding apparatus is mounted on the measurement platform and configured to convey the to-be-measured flexible photovoltaic module to a position corresponding to the height measurer.

Preferably, there are further provided a remote control transmitter and a remote control receiver, wherein the remote control receiver is connected with a motor controller of the sliding apparatus, the remote control transmitter is configured to send a control instruction, and the control instruction is configured to control a transfer direction and a transfer distance of the sliding apparatus, and the remote control receiver is configured to receive the control instruction and control a motor to execute a corresponding action.

Preferably, there is further provided an image-taking apparatus, wherein the image-taking apparatus is disposed on the measurement platform and configured to take an image of a positional relation between the height measurer and the to-be-measured flexible photovoltaic module.

The present disclosure further provides a method for measuring flatness of a flexible photovoltaic module, which is applied to the above-mentioned device for measuring flatness of a flexible photovoltaic module, comprising:
sending a measurement instruction to the lift rack, so that the lift rack performs, after acquiring the measurement instruction, a lowering operation based on the measurement instruction, until the height measurers respectively correspond to the wave crests and the wave troughs on the to-be-measured flexible photovoltaic module,
collecting position information of the to-be-measured flexible photovoltaic module when the height measuring probes come into contact with a surface of the to-be-measured flexible photovoltaic module, and
judging, based on the position information, whether the to-be-measured flexible photovoltaic module is qualified.

Preferably, the judging, based on the position information, whether the to-be-measured flexible photovoltaic module is qualified comprises:
calculating a difference value between height values of any pair of adjacent wave crest and wave trough to obtain a plurality of difference values, and
judging, based on the plurality of difference values, whether the to-be-measured flexible photovoltaic module is qualified.

Preferably, the judging, based on the plurality of difference values, whether the to-be-measured flexible photovoltaic module is qualified comprising:
determining that the to-be-measured flexible photovoltaic module is not qualified, if it is judged that there exists a difference value among the plurality of difference values that is greater than a preset numerical value, or
determining that the to-be-measured flexible photovoltaic module is not qualified, if it is judged that N difference value(s) of the plurality of difference values is (are) greater than the preset numerical value.

According to the method and the device for measuring flatness of a flexible photovoltaic module provided by the present disclosure, by lowering of the lift rack, the height measurers are driven to come into contact with the respective wave crests and wave troughs on the to-be-measured flexible photovoltaic module, so as to measure the heights of the wave crests and the wave troughs, measurement is effected upon the contact of the height measurers to the to-be-measured flexible photovoltaic module, when the height measurers are lowered with the lift rack, which reduces measurement errors brought forth by the fact that the measurement cannot be performed in proper time due to local deformation of the cell module, moreover, due to the presence of the support of the lift rack, there is no need to manually move the measuring device back and forth, which thereby reduces the measuring device's scratching the to-be-measured flexible photovoltaic module, and in addition, the present disclosure enables direct and simultaneous measurement of a plurality of wave crests and wave troughs, which greatly improves the measuring efficiency, and the arrangement of the controller makes it possible to directly make an automatic judgment as to whether the to-be-measured flexible photovoltaic module is qualified, thereby further improving the working efficiency.

### BRIEF DESCRIPTION OF THE DRAWINGS

FIG. 1 is a schematic structural diagram of a device for measuring flatness of a flexible photovoltaic module according to an embodiment of the present disclosure.

FIG. 2 is a front view of the arrangement mode between a measurement platform and a sliding apparatus according to an embodiment of the present disclosure.

FIG. 3 is a schematic diagram of an optional sliding apparatus control method according to an embodiment of the present disclosure.

FIG. 4 is a schematic structural diagram of an optional device for measuring flatness of a flexible photovoltaic module according to an embodiment of the present disclosure.

FIG. 5 is a schematic structural diagram of another optional device for measuring flatness of a flexible photovoltaic module according to an embodiment of the present disclosure.

FIG. 6 is a flowchart of a method for measuring flatness of a flexible photovoltaic module according to an embodiment of the present disclosure.

FIG. 7 is a flowchart of a first optional method for measuring flatness of a flexible photovoltaic module according to an embodiment of the present disclosure.

FIG. 8 is a flowchart of a second optional method for measuring flatness of a flexible photovoltaic module according to an embodiment of the present disclosure.

### REFERENCE SIGNS

1—measurement platform, 2—to-be-measured flexible photovoltaic module, 31—support frame, 32—lifting drive unit, 4—height measurer, 5—controller, 6—display, 7—positioning apparatus, 8—sliding apparatus, 91—remote control receiver, 92—remote control transmitter, and 10—image-taking apparatus.

### DETAILED DESCRIPTION OF THE EMBODIMENTS

The embodiments of the present disclosure are described in detail below, and the examples of the embodiments are shown in the accompanying drawings, throughout which the same or similar reference signs denote the same or similar elements or elements having the same or similar functions. The embodiments described below with reference to the accompanying drawings are exemplary and merely serve to explain the present disclosure, and cannot be construed as limiting the present disclosure.

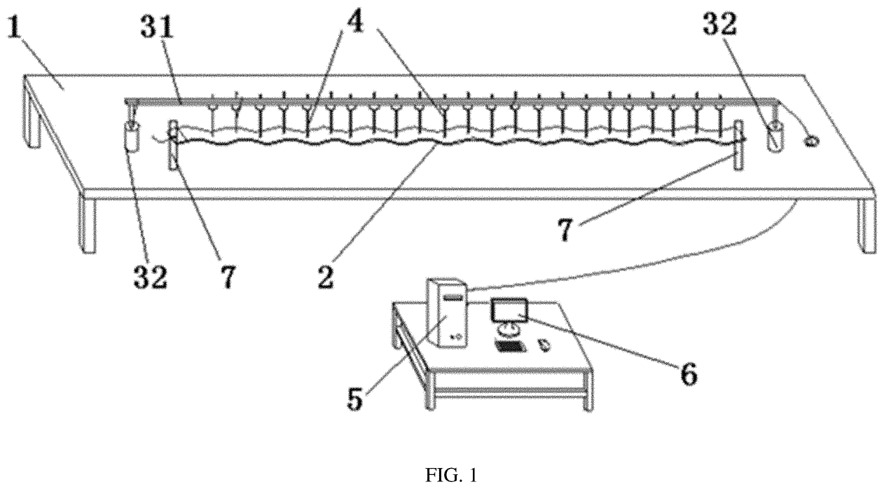

As shown in FIG. 1, an embodiment of the present disclosure provides a device for measuring flatness of a flexible photovoltaic module, comprising: a measurement platform 1 configured to fix a to-be-measured flexible photovoltaic module 2, height measurers 4 respectively corresponding to wave crests and wave troughs on the to-be-measured flexible photovoltaic module 2, the plurality of height measurers 4 are located above the measurement platform 1, and a lift rack, the plurality of height measurers 4 are disposed on the lift rack.

In operation, the height measurers 4 are located above the to-be-measured flexible photovoltaic module 2 and each of the height measurers 4 respectively corresponds to the wave crest and the wave trough on the to-be-measured flexible photovoltaic module 2, the lowering of the lift rack causes the height measurers 4 to come into contact with the respective wave crests and wave troughs, and to sense the height of the surface of the to-be-measured flexible photovoltaic module 2 by means of its slight contact with the surface of the to-be-measured flexible photovoltaic module 2, thereby measuring the height of the wave crests and the wave troughs.

In the above, the lift rack is generally disposed on the measurement platform 1. However, the lift rack is not limited to this arrangement, i.e., merely on the measurement platform 1, instead, it may be disposed on the ground, or suspended from the top of a processing workshop by a lifting rope and perform lifting and lowering in a suspended manner, or may be disposed in other ways, as long as lifting and lowering can be realized.

According to the device for measuring flatness of a flexible photovoltaic module provided by the present disclosure, the lift rack can be flexibly lifted and lowered, by lowering of the lift rack, the height measurers 4 are driven to come into contact with the respective wave crests and wave troughs on the to-be-measured flexible photovoltaic module 2, so as to measure the height of the wave crests and the wave troughs, measurement is effected upon the contact of the height measurers with the to-be-measured flexible photovoltaic module 2, when the height measurers 4 are lowered with the lift rack, which reduces measurement errors brought forth by the fact that the measurement cannot be performed in proper time due to local deformation of the cell module, moreover, due to the presence of the support of the lift rack, there is no need to manually move the measuring device back and forth, which thereby avoids the measuring device's scratching the to-be-measured flexible photovoltaic module 2, and in addition, the present disclosure enables direct and simultaneous measurement of a plurality of wave crests and wave troughs, which greatly improves the measuring efficiency.

In the embodiments of the present disclosure, the following two application scenarios can be adopted.

Scenario 1: The Lift Rack being Disposed on the Measurement Platform 1

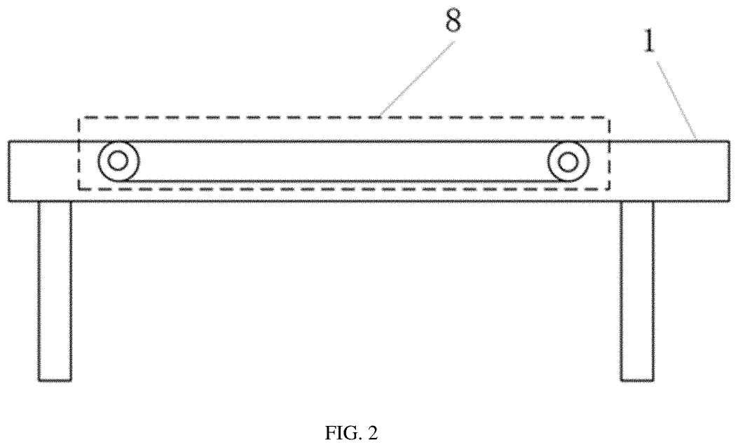

In this case, as shown in FIG. 1, it is feasible to detachably mount the lift rack on the measurement platform, and making, by the lifting and lowering of the lift rack, the height measurers 4 respectively correspond to the wave crests and the wave troughs on the to-be-measured flexible photovoltaic module 2. At this time, as shown in FIG. 2, a sliding apparatus 8 can be arranged on the measurement platform, wherein the sliding apparatus 8 is configured to convey the to-be-measured flexible photovoltaic module to a position corresponding to the height measurer.

Generally, the positions of the wave crests and the wave troughs are different on different to-be-measured flexible photovoltaic modules 2, but the positions of the height measurers 4 are generally fixed. Therefore, by means of the sliding apparatus 8, it is possible to realize respectively corresponding the height measurers 4 respectively to the wave crests and the wave troughs on the to-be-measured flexible photovoltaic module 2. The sliding apparatus 8 may be a transmission mechanism (a conveyor belt), or any means capable of sliding leftward or rightward.

When the sliding apparatus 8 is a transmission mechanism, a user can dispose the to-be-measured flexible photovoltaic module 2 on the transmission mechanism. After the measurement of the to-be-measured flexible photovoltaic module 2 is started, the transmission mechanism starts to move, and stops moving when the transmission mechanism moves to a target position, wherein the target position may be a preset fixed position. If the wave crests and the wave troughs on the current to-be-measured flexible photovoltaic module 2 do not correspond to the height measurers 4, it is feasible to make the wave crests and the wave troughs on the current to-be-measured flexible photovoltaic module 2 correspond to the height measurers 4 by adjusting the transmission mechanism.

In an embodiment of this present disclosure, the transmission mechanism can be adjusted by a controller 5 described as follows. For example, one or more control switches are provided in the controller 5, by means of which control switches the transmission mechanism is controlled to be driven leftward or rightward, until the wave crests and the wave troughs on the current to-be-measured flexible photovoltaic module 2 correspond to the height measurers 4.

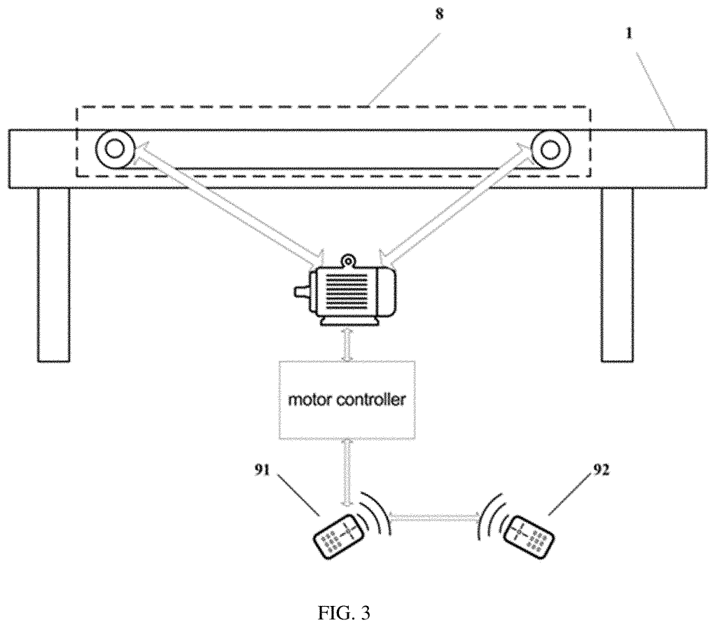

As shown in FIG. 3, it is also feasible to adjust the transmission mechanism by means of a remote control transmitter 92 and a remote control receiver 91 that are independent of the controller 5, in addition to the control switches. Specifically, a control instruction is sent via the remote control transmitter 92, wherein the control instruction is used for controlling the transfer direction and the transfer distance of the transmission mechanism, after the remote control receiver 91 receives the control instruction, a motor is controlled by a motor controller connected thereto to execute a corresponding action, for example, forward rotation or reverse rotation, thereby realizing leftward drive or rightward drive of the transmission mechanism. Here, the remote control receiver 91 is connected with the motor controller of the transmission mechanism.

Scenario 2: The Lift Rack being Suspended from the Top of the Processing Workshop by a Lifting Rope and Performing Lifting and Lowering in a Suspended Manner

In this case, the lift rack can be suspended from the top of a processing workshop by a lifting rope and perform lifting and lowering in a suspended manner, and by lifting and lowering the lift rack, the height measurers 4 are caused to respectively correspond to the wave crests and the wave troughs on the to-be-measured flexible photovoltaic module 2. When the lift rack is suspended from the top of a processing workshop by a lifting rope, the lift rack can slide leftward or rightward by means of a slide rail, here the slide rail is arranged at the top of the processing workshop.

In the present embodiment, a sliding apparatus can further be arranged on the measurement platform, wherein the sliding apparatus is configured to convey the to-be-measured flexible photovoltaic module to a position corresponding to the height measurer. Here, the sliding apparatus may be a transmission mechanism (e.g., a conveyor belt), or any means capable of sliding leftward or rightward.

At the time of performing measurement on the to-be-measured flexible photovoltaic module 2, the lifting and lowering of the lift rack can be controlled by the lifting rope. When the lift rack is lowered to a position where the height measures 4 come into contact with the to-be-measured flexible photovoltaic module 2, if the height measurers 4 do not respectively correspond to the wave crests and the wave troughs on the to-be-measured flexible photovoltaic module 2, it is feasible to make the height measurers 4 respectively correspond to the wave crests and the wave troughs on the to-be-measured flexible photovoltaic module 2 by adjusting the position of the lift rack. In addition to this, it is also feasible to adjust the sliding apparatus so as to make the height measurers 4 respectively correspond to the wave crests and the wave troughs on the to-be-measured flexible photovoltaic module 2.

When the wave crests and the wave troughs on the to-be-measured flexible photovoltaic module are not in one-to-one correspondence with the height measurers, as can be known from the above description, in the present embodiment, the height measurers can be adjusted by means of the combination of the sliding apparatus and the lift rack, or the to-be-measured flexible photovoltaic module can be adjusted. Based on this, in this embodiment, there is no need for a worker to manually adjust the height measurers or the to-be-measured flexible photovoltaic module repeatedly, thus simplifying the measurement flow. Especially when the to-be-measured flexible photovoltaic module is placed in an area out of reach of the worker, accurate measurement of the flatness of the flexible photovoltaic module can be realized in the above-mentioned ways.

Preferably, as shown in FIG. 1, the lift rack comprises a support frame 31 and a lifting drive unit 32, wherein the plurality of height measurers 4 are sequentially disposed on the support frame 31, and the support frame 31 is fixed on the measurement platform 1 via the lifting drive unit 32. Preferably, the lifting drive unit 32 comprises two cylinders, the telescopic rods of the two cylinders are connected with the two ends of the support frame 31, respectively, and the cylinder bodies of the two cylinders are both fixed on the measurement platform 1. As will be appreciated by those skilled in the art, the lifting drive unit 32 may also adopt the structures such as a hydraulic cylinder, a spring and an electric telescopic rod.

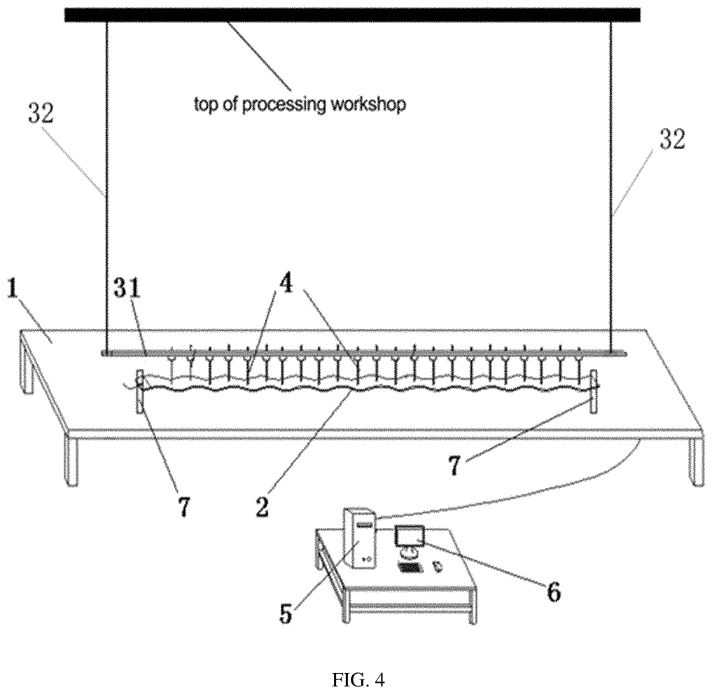

Preferably, as shown in FIG. 4, the lifting drive unit 32 may also be a lifting rope, wherein the lifting rope extends downward from the top of the processing workshop and is connected with the support frame 31, thereby realizing the lifting and lowering drive of the support frame 31. In order to improve the suspension stability, a plurality of lifting ropes may be provided. For example, a plurality of lifting ropes are provided at both ends of the support frame 31, or at least one lifting rope is provided on the support frame 31 at a certain interval. Of course, the lifting drive unit is not limited to those listed, which, however, will not be described in detail herein.

Preferably, the height measurer 4 is a height measuring probe, and the plurality of height measuring probes are arranged in a straight line. The height measuring probe mainly serves to sense the height of the surface of the to-be-measured flexible photovoltaic module 2 via the slight contact between the probe and the surface of the to-be-measured flexible photovoltaic module 2, and is a functional unit and a core component of the whole measuring system, and the height measuring probes are arranged in a row, i.e. on the same vertical plane.

Preferably, the device for measuring flatness of a flexible photovoltaic module further comprises a data collector, and the data collector is connected with each of the height measurers 4. Preferably, the device for measuring flatness of a flexible photovoltaic module further comprises a controller 5, and the controller 5 is connected with both the lifting drive unit 32 and the data collector. Preferably, the device for measuring flatness of a flexible photovoltaic module further comprises a display 6, and the display 6 is connected with the controller 5.

It should be noted that, in this embodiment, the controller 5 may be an upper computer, test software is installed in this upper computer, and by means of the test software, it is possible to control the height measurer.

As shown in FIG. 1, the controller 5 and the display 6 may be disposed on the measurement platform 1, or may be disposed at other positions, which is not particularly limited in this embodiment. The controller is connected with the lifting drive unit 32, and when the lifting drive unit 32 is two cylinders, the controller can realize the lifting and lowering of the lifting drive unit 32 by controlling the two cylinders.

In an embodiment of the present disclosure, the controller 5 is further connected with the data collector and is configure to acquire the height data collected by the data collector. The display 6 is connected with the controller 5 and is configured to display the height data collected by the data collector.

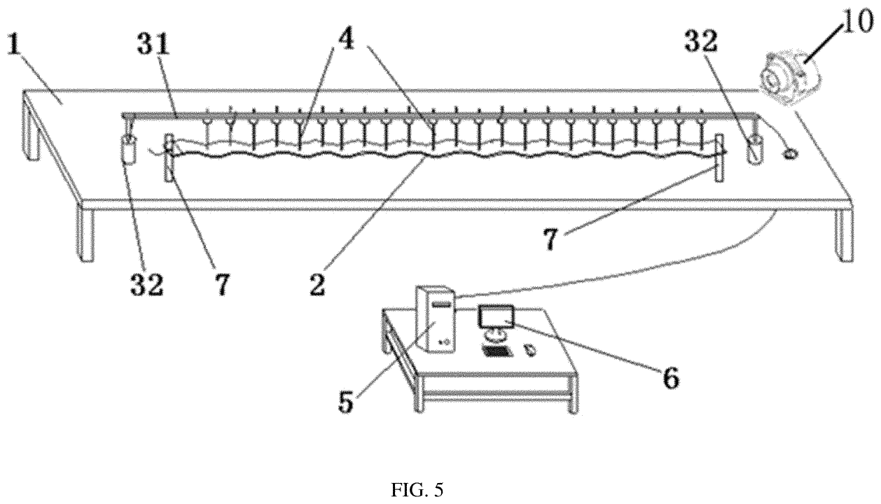

It should be noted that, in the present embodiment, as shown in FIG. 5, there is further provided image-taking apparatus 10, wherein the image-taking apparatus 10 is disposed on the measurement platform, and is connected with the controller 5 and is configured to take an image or video stream of the positional relation between the height measurers and the to-be-measured flexible photovoltaic module. After the image or video stream is obtained, the image or video stream can be sent to the controller 5 and the image or video stream can be displayed with the display 6.

When the device for measuring flatness of a flexible photovoltaic module is placed in a work environment that cannot be reached by a user, it is possible to adjust, based on the image or video stream captured by the image-taking apparatus, the position of the to-be-measured flexible photovoltaic module or the position of the height measurers, such that the wave crests and the wave troughs on the to-be-measured flexible photovoltaic module respectively correspond to the height measurers.

In this embodiment, the data collector, the controller 5 and the display 6 are all data processing systems. The data collector collects the height values of the wave crests and the wave troughs measured by the height measuring probes, and then transmits the height values to the controller 5 for processing and automatic judging as to whether the to-be-measured flexible photovoltaic module is qualified. Of course, in the practical application, these operations can also be realized by a microcomputer, that is, processing and automatic judging programs are set therein, and the operations can be automatically performed by clicking the programs, which greatly improves the working efficiency. The display 6 can display each height value measured, the result of judgment as to whether the to-be-measured flexible photovoltaic module is qualified, etc., which can be flexibly set according to actual needs.

In the present embodiment, when making an automatic judgment on the height data collected by the data collector, the controller 5 can calculate the difference value between the height values of any pair of adjacent wave crest and wave trough, thereby obtaining a plurality of difference values. After the plurality of difference values are obtained, it is possible to judge, based on the plurality of difference values, whether the to-be-measured flexible photovoltaic module is qualified, for example, determining that the to-be-measured flexible photovoltaic module is not qualified, if it is judged that there exists a difference value among the plurality of difference values that is greater than a preset numerical value, or determining that the to-be-measured flexible photovoltaic module is not qualified, if it is judged that N difference value(s) of the plurality of difference values is (are) greater than the preset numerical value. The specific judgment conditions may be set according to actual needs, and are not specifically defined in the present embodiment, wherein N is a positive integer greater than zero.

Preferably, the support frame 31 is provided thereon with a slide rail, and the height measurers 4 are slidably mounted on the slide rail. That is, the height measurers 4 are sequentially arranged on the slide rail and are slidable on the slide rail. Preferably, the device for measuring flatness of a flexible photovoltaic module further comprises a positioning clamping element, and the positioning clamping element is disposed on the slide rail and configured to position each of the height measurers 4. The arrangement of the slide rail enables to flexibly adjust the positions of the height measurers 4, which facilitates practical testing.

Preferably, the device for measuring flatness of a flexible photovoltaic module further comprises a positioning apparatus 7, the positioning apparatus 7 is disposed on the measurement platform 1 and the positioning apparatus 7 is configured to fix the to-be-measured flexible photovoltaic module 2. Generally, the structures such as a fixation clamp can be adopted, as long as they can realize fixing the to-be-measured flexible photovoltaic module 2.

In an embodiment of the present disclosure, the positioning apparatus 7 may be plural in number, for example, as shown in FIG. 1, the number of the positioning apparatus 7 is two, and the two positioning apparatus 7 are used for fixing the two ends of the to-be-measured flexible photovoltaic module 2, respectively.

It should be noted that, in an embodiment of the present disclosure, if the measurement platform 1 is mounted thereon with a sliding apparatus, the positioning apparatus 7 can be used to fix the sliding apparatus. In this case, the number of the positioning apparatus 7 is not limited to 2, for example, it may be 3, 4, etc., and the specific number can be set according to actual needs.

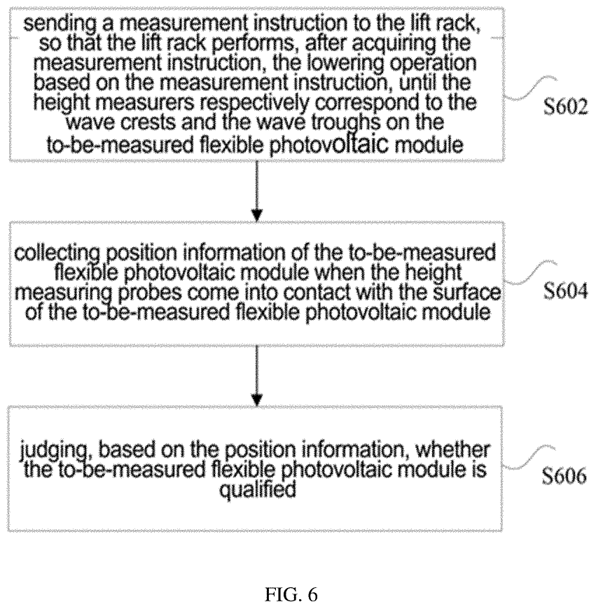

Referring to FIG. 6, it is a flowchart of a method for measuring flatness of a flexible photovoltaic module provided by an embodiment of the present disclosure. It should be noted that the method provided by this embodiment is not limited to the specific order in FIG. 6 or described below. The steps shown in FIG. 6 will be described in detail below.

Step S602: sending a measurement instruction to the lift rack, wherein the measurement instruction may be sent to the lift rack via the controller, so that the lift rack performs, after acquiring the measurement instruction, the lowering operation based on the measurement instruction, until the height measurers respectively correspond to the wave crests and the wave troughs on the to-be-measured flexible photovoltaic module,

Step S604, collecting position information of the to-be-measured flexible photovoltaic module when the height measuring probes come into contact with the surface of the to-be-measured flexible photovoltaic module, wherein the position information of the to-be-measured flexible photovoltaic module can be collected by the data collector, and

Step S606, judging, based on the position information, whether the to-be-measured flexible photovoltaic module is qualified, wherein whether the to-be-measured flexible photovoltaic module is qualified can be judged by a controller based on the position information.

It should be noted that the controller in this embodiment is the controller in the preceding embodiment of the device for measuring flatness of a flexible photovoltaic module.

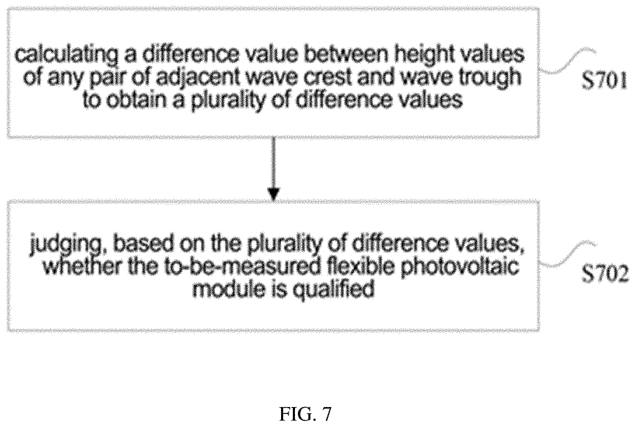

Optionally, as shown in FIG. 7, the judging, based on the position information, whether the to-be-measured flexible photovoltaic module is qualified comprises the following steps:

Step S701, calculating a difference value between height values of any pair of adjacent wave crest and wave trough to obtain a plurality of difference values, and step S702: judging, based on the plurality of difference values, whether the to-be-measured flexible photovoltaic module is qualified.

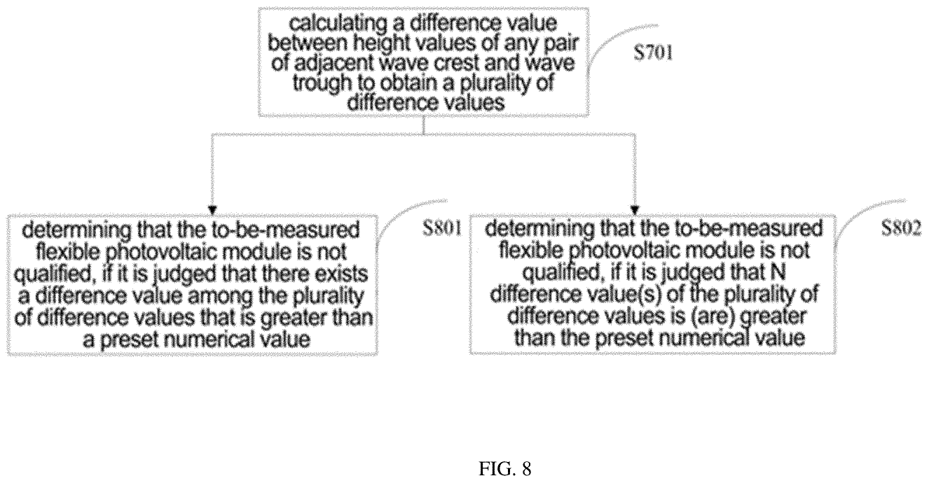

Optionally, as shown in FIG. 8, the judging, based on the plurality of difference values, whether the to-be-measured flexible photovoltaic module is qualified comprises: step S801, determining that the to-be-measured flexible photovoltaic module is not qualified, if it is judged that there exists a difference value among the plurality of difference values that is greater than a preset numerical value, or step S802, determining that the to-be-measured flexible photovoltaic module is not qualified, if it is judged that N difference values of the plurality of difference values is (are) greater than the preset numerical value.

The specific measuring steps of the present disclosure are as follows:

1. confirming that there are no other sundries on the measurement platform 1, and confirming that the height measuring probes are in a risen state (i.e., the cylinders are in an extended state),

2. placing the to-be-measured flexible photovoltaic module 2, so that the to-be-measured flexible photovoltaic module 2 is fixed at the same position at the time of each measurement, and the points of the wave crests and the wave troughs thereof each respectively face the positions of the height measuring probes directly,

3. clicking a test option of the test software on the computer (or the controller), so that the cylinder will automatically go up and the height measuring probes will come into contact with the surface of the to-be-measured flexible photovoltaic module 2, wherein since the height measuring probes can move up and down relative to the to-be-measured flexible photovoltaic module 2, the height measuring probes will not touch and hurt the to-be-measured flexible photovoltaic module 2, the height measuring probes will collect the position information of the to-be-measured flexible photovoltaic module 2 when coming into contact with the surface of the to-be-measured flexible photovoltaic module 2, so that the surface height of the corresponding position of the to-be-measured flexible photovoltaic module 2 is calculated via the controller 5, and with a pre-designed algorithm, it can be judged whether the flatness of the to-be-measured flexible photovoltaic module 2 reaches the standard (the specific process is as described above, and will not be described herein), and after the data collection is completed, the cylinder will automatically go up, and the test is completed, and

4. taking out the to-be-measured flexible photovoltaic module 2, and testing the next to-be-measured flexible photovoltaic module 2.

The structures, features and effects of the present disclosure have been described in detail above on the basis of the embodiments shown with reference to the drawings. The above description is merely preferred embodiments of the present disclosure, and the scope of implementation of the present disclosure is not limited to what is shown in the drawings. Any change made in accordance with the concept of the present disclosure or any equivalent embodiment without departing from the spirit covered by the description and the drawings shall be covered by the scope of protection of the present disclosure.

### INDUSTRIAL APPLICABILITY

The device for measuring flatness of a flexible photovoltaic module provided by the present disclosure can reduce measurement errors brought forth by the fact that the measurement cannot be performed in proper time due to local deformation of the cell module, moreover, due to the presence of the support of the lift rack, there is no need to manually move the measuring device back and forth, which thereby reduces the measuring device's scratching the to-be-measured flexible photovoltaic module, and in addition, the present disclosure enables direct and simultaneous measurement of a plurality of wave crests and wave troughs, which greatly improves the measuring efficiency, and the arrangement of the controller makes it possible to directly make an automatic judgment as to whether the to-be-measured flexible photovoltaic module is qualified, thereby further improving the working efficiency.

1. A device for measuring flatness of a flexible photovoltaic module, comprising:
a measurement platform configured to fix a to-be-measured flexible photovoltaic module,
height measurers sequentially corresponding to wave crests and wave troughs on the to-be-measured flexible photovoltaic module, wherein the plurality of height measurers are all located above the measurement platform, and
a lift rack, on which the plurality of height measurers is disposed.

2. The device for measuring flatness of a flexible photovoltaic module according to claim 1, wherein the lift rack is disposed on the measurement platform, on the ground, or in suspension.

3. The device for measuring flatness of a flexible photovoltaic module according to claim 1, wherein the lift rack comprises a support frame and a lifting drive unit, wherein the plurality of height measurers are sequentially disposed on the support frame, and the support frame is fixed on the measurement platform via the lifting drive unit.

4. The device for measuring flatness of a flexible photovoltaic module according to claim 3, wherein the lifting drive unit comprises two cylinders, telescopic rods of the two cylinders are connected with two ends of the support frame, respectively, and cylinder bodies of the two cylinders are both fixed on the measurement platform.

5. The device for measuring flatness of a flexible photovoltaic module according to claim 3, wherein the lifting drive unit comprises a lifting rope, and the lifting rope is connected with the support frame.

6. The device for measuring flatness of a flexible photovoltaic module according to claim 1, wherein the height measurer is a height measuring probe, and the plurality of height measuring probes are arranged in a straight line.

7. The device for measuring flatness of a flexible photovoltaic module according to claim 3, further comprising a data collector, wherein the data collector is connected with each of the height measurers.

8. The device for measuring flatness of a flexible photovoltaic module according to claim 7, further comprising a controller, wherein the controller is connected with both the lifting drive unit and the data collector.

9. The device for measuring flatness of a flexible photovoltaic module according to claim 8, further comprising a display, wherein the display is connected with the controller.

10. The device for measuring flatness of a flexible photovoltaic module according to claim 3, wherein the support frame is provided thereon with a slide rail, and the height measurers are slidably mounted on the slide rail.

11. The device for measuring flatness of a flexible photovoltaic module according to claim 10, further comprising a positioning clamping element, wherein the positioning clamping element is disposed on the slide rail and configured to position each of the height measurers.

12. The device for measuring flatness of a flexible photovoltaic module according to claim 1, further comprising a positioning apparatus, wherein the positioning apparatus is disposed on the measurement platform and the positioning apparatus is configured to fix the to-be-measured flexible photovoltaic module, and the positioning apparatus is plural in number.

13. The device for measuring flatness of a flexible photovoltaic module according to claim 1, further comprising:
a sliding apparatus, wherein the sliding apparatus is mounted on the measurement platform and configured to convey the to-be-measured flexible photovoltaic module to a position corresponding to the height measurer.

14. The device for measuring flatness of a flexible photovoltaic module according to claim 13, further comprising: a remote control transmitter and a remote control receiver, wherein the remote control receiver is connected with a motor controller of the sliding apparatus,
the remote control transmitter is configured to send a control instruction, wherein the control instruction is configured to control a transfer direction and a transfer distance of the sliding apparatus, and
the remote control receiver is configured to receive the control instruction and controls a motor to perform a corresponding action.

15. The device for measuring flatness of a flexible photovoltaic module according to claim 1, further comprising: an image-taking apparatus, wherein the image-taking apparatus is disposed on the measurement platform and configured to take an image of a positional relation between the height measurer and the to-be-measured flexible photovoltaic module.

16. A method for measuring flatness of a flexible photovoltaic module, applied to the device for measuring flatness of a flexible photovoltaic module according to claim 1, comprising:
sending a measurement instruction to the lift rack, so that the lift rack performs, after acquiring the measurement instruction, a lowering operation based on the measurement instruction, until the height measurers sequentially correspond to the wave crests and the wave troughs on the to-be-measured flexible photovoltaic module,
collecting position information of the to-be-measured flexible photovoltaic module when the height measuring probes come into contact with a surface of the to-be-measured flexible photovoltaic module, and
judging, based on the position information, whether the to-be-measured flexible photovoltaic module is qualified.

17. The method for measuring flatness of a flexible photovoltaic module according to claim 16, wherein the judging, based on the position information, whether the to-be-measured flexible photovoltaic module is qualified comprises:
calculating a difference value between height values of any pair of adjacent wave crest and wave trough to obtain a plurality of difference values, and
judging, based on the plurality of difference values, whether the to-be-measured flexible photovoltaic module is qualified.

18. The method for measuring flatness of a flexible photovoltaic module according to claim 17, wherein the judging, based on the plurality of difference values, whether the to-be-measured flexible photovoltaic module is qualified comprises:
determining that the to-be-measured flexible photovoltaic module is not qualified, if it is judged that there exists a difference value among the plurality of difference values that is greater than a preset numerical value, or
determining that the to-be-measured flexible photovoltaic module is not qualified, if it is judged that N difference value(s) of the plurality of difference values is (are) greater than the preset numerical value.

19. The device for measuring flatness of a flexible photovoltaic module according to claim 2, further comprising:
a sliding apparatus, wherein the sliding apparatus is mounted on the measurement platform and configured to convey the to-be-measured flexible photovoltaic module to a position corresponding to the height measurer.

20. The device for measuring flatness of a flexible photovoltaic module according to claim 2, further comprising: an image-taking apparatus, wherein the image-taking apparatus is disposed on the measurement platform and configured to take an image of a positional relation between the height measurer and the to-be-measured flexible photovoltaic module.
